(19) United States
(12) Patent Application Publication
(10) Pub. No.: US 2007/0152763 A1
(43) Pub. Date: Jul. 5, 2007

(54) Voltage controlled oscillator

(76) Inventor: Mozhgan Mansuri, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/323,100

(22) Filed: Dec. 30, 2005

(51) Int. Cl. H03K 3/03

(52) U.S. Cl. 331/57

(57) ABSTRACT

Disclosed herein are embodiments of voltage controlled oscillator circuits with pseudo differential inverter stages.

### BACKGROUND

Voltage-controlled oscillators (VCOs) are commonly used in integrated circuits for a variety of applications such as phase-locked loop (PLL) circuits. Ring oscillators are widely used in VCOs, among other reasons, due to their wide tuning range, ease of implementation, and relatively small die area.

FIG. 1 shows a conventional differential ring oscillator circuit 100. It comprises a self-biasing circuit 102 and four cascaded, differential inverter stages 104 with the last stage being cross-coupled back to the first stage thereby allowing for an even number of stages. Each stage 104 comprises a differential amplifier formed from symmetric loads 106, input transistors 108, and a current source transistor 110.

In response to an input frequency control signal (VCTL), the self biasing circuit 102 biases the symmetric loads 106 with a PBIAS signal and biases the current sources 110 with an NBIAS signal to control the oscillator's output frequency. The output frequency is inversely proportional to an RC time constant Where the R term comes from the resistance of the symmetric loads 106. Thus, by varying symmetric load resistance via the self-bias circuit 102, the frequency can be varied over a relatively wide range. Unfortunately, this design has poor phase noise performance due to the high number of devices which introduces more device noise. Another problem is that each stage's current source 110 consumes relatively large DC current resulting in inefficient power consumption. Also, despite the fact that the self-bias circuit 102 partially rejects supply noise, this design has a poor power supply noise rejection ratio (PSRR) due to relatively large voltage to frequency conversion gain resulting from the symmetric loads whose resistance is affected, e.g., with noise in the supply.

FIG. 2 shows another conventional ring oscillator circuit 200 that uses pseudo differential inverter stages instead of differential stages. (The term “pseudo differential” refers to the fact that the inverter stages have complementary (differential) outputs but do not necessarily use a differential amplifier with a current source, as would be the case with a differential amplifier as it is commonly understood. The differential output allows for an even or odd number of stages to be used in the ring oscillator design.) As with the previous ring oscillator, four stages (204) are cascaded together with the last stage cross-coupled back to the first stage. A control voltage (VCTL_INT) generated by a voltage regulator 202, in response to an applied command voltage (VCTL), controls the frequency of the oscillator. As the control voltage goes up, frequency goes up and vice versa.

Each pseudo differential stage 204 comprises a complementary inverter (an inverter with complementary inputs and outputs) formed from cross-coupled, mirrored NMOS transistor pairs 208. The inverters also have a PMOS transistor 206 in each of their pull-up legs. As indicated, the input of each pull-up device 206 is coupled to the inverter input (In+ or In−) on the same side as the PMOS device. (The term “PMOS transistor” refers to a P-type metal oxide semiconductor field effect transistor. Likewise, “NMOS transistor” refers to an N-type metal oxide semiconductor field effect transistor. (It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs and oxide thicknesses to mention just a few. Moreover, unless specifically referred to as MOS or the like, the term transistor can include other suitable transistor types, e.g., junction-field-effect transistors, bipolar-junction transistors, and various types of three dimensional transistors, known today or not yet developed.)

Both PMOS and NMOS transistors function as variable resistance loads for changing the output frequency in response to changes in the internal control voltage (VCTL_INT). As the control voltage decreases, the load resistances go up, which decreases the output frequency. Conversely, as the control voltage increases, load resistance goes down, which causes the frequency to go up. This pseudo differential ring oscillator design has better phase noise performance compared with circuit 200 for a given power consumption. However, it suffers from poor supply noise sensitivity. As with the differential design discussed previously, it has high control voltage to frequency conversion gain. Thus, any supply noise in the control voltage translates to jitter at the output. Accordingly, to alleviate this problem, a voltage regulator 202 with high power supply rejection ratio (PSRR) may be required. Unfortunately, voltage regulators with high PSRR cost power and area. Accordingly, an improved VCO is desired.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a conventional differential ring oscillator circuit.

FIG. 2 is a schematic diagram of a conventional pseudo differential ring oscillator circuit.

FIG. 3A is a schematic diagram of a pseudo differential ring oscillator circuit in accordance with some embodiments of the present invention.

FIG. 3B is a schematic diagram of a controllably variable linear resistor in accordance with some embodiments.

FIG. 4 is a block diagram of a computer system having a microprocessor with at least one pseudo differential ring oscillator circuit in accordance with some embodiments.

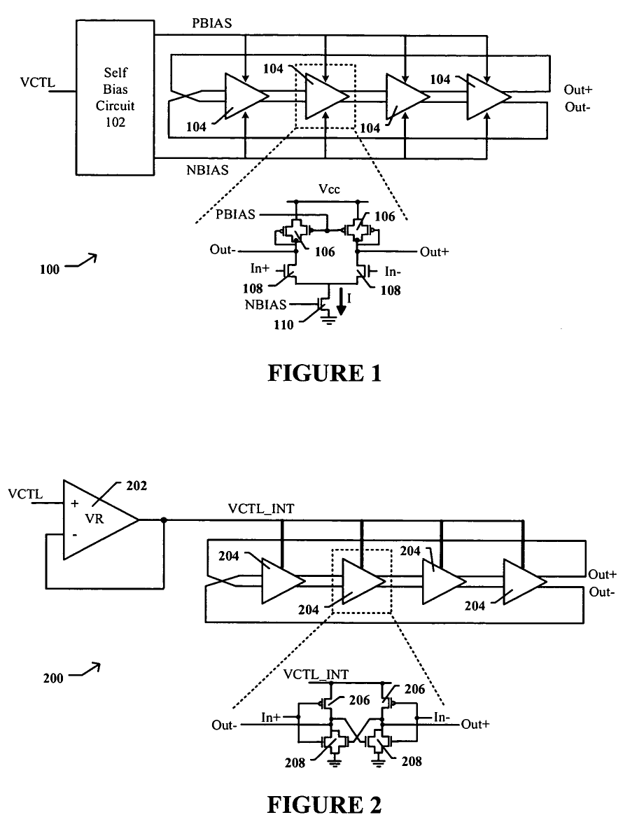

### DETAILED DESCRIPTION

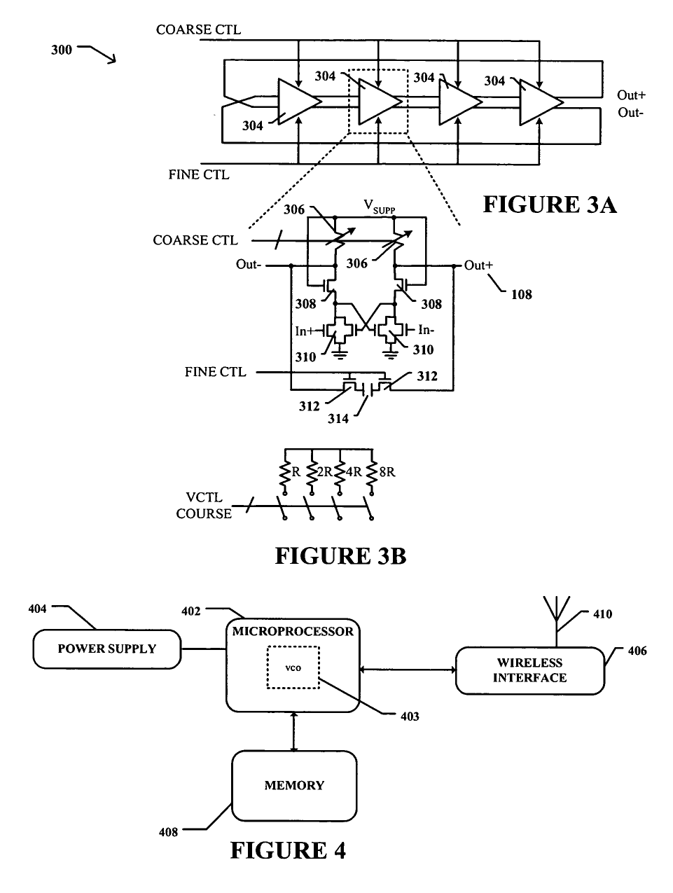

FIG. 3A shows a pseudo differential ring oscillator circuit 300 in accordance with some embodiments. The depicted ring oscillator circuit 300 comprises four cascaded pseudo inverters 304 with the output stage cross-coupled back to the first stage. It generates a differential output clock at its output (Out+/Out−) whose frequency is determined by coarse and fine control signal levels (COARSE CTL and FINE CTL, respectively). (Note that while the oscillator is shown with four stages, any desired number could be used. Moreover, the depicted oscillator has both coarse and fine control signal settings, but it should be appreciated that other embodiments may implement only a coarse or a fine setting.)

As indicated, each pseudo inverter stage 304 comprises a complementary inverter formed from cross-coupled NMOS pairs 310. The complementary inverter has first and second pull-up legs. In the depicted figure, the negative output node (Out−) is associated with the first pull-up leg, while the positive output node (Out+) is associated with the second pull-up leg. In each leg, a separate controllably variable linear resistor 306 and NMOS transistor 308 are coupled in series between a supply voltage (V_{SUPP}) and a mirrored NMOS pair 310. They function as pull-up devices with controllably variable loads. The input to each pull-up NMOS device 308 is coupled to the supply voltage (V_{SUPP}), while the coarse control signal (COARSE CTL) is coupled to a resistance setting input for each controllably variable resistor 306. (Note that in the depicted embodiment, a cross-coupled mirrored NMOS pairs and pull-up legs having NMOS transistors are used. However, it should be appreciated that a complementary design (cross-coupled PMOS mirror pairs with pull-down legs) could also be implemented and is contemplated herein.)

As used herein, a controllably variable linear resistor refers to a variable resistor whose resistance is not materially affected by changes in voltage applied across it. For example, a linear resistor may be made, e.g., from poly or some other suitable material used for implementing resistors in a semiconductor process. With reference to FIG. 3B, in some embodiments, a controllably variable linear resistor 306 may be implemented with several fixed resistors each coupled in series to a switch (e.g., transistor) all coupled together in parallel. The resistor values can be unequally weighted (e.g., binary weighted) so that by enabling a particular combination of the switches, a desired resistance from a wide variety of resistance options can be obtained. In general, the coarse control signal should be in accordance (e.g., analog, digital) with the particular resistor design used to implement the controllably variable resistor 306. With the variable resistor of FIG. 3B, for example, a 4-bit bus could be used to implement the coarse control signal.

Returning to FIG. 3A, a pseudo differential inverter 300 may also include a variable capacitance to implement, e.g., a fine tune frequency adjustment capability. In the depicted inverter circuit, a capacitor 314 is coupled between control transistors 312, which are coupled between the first and second pull-up legs. An analog control signal (CTL FINE) is coupled to the gates of transistors 312 to variably couple the capacitor 314 into the inverter. That is, in this embodiment, the CTL FINE signal has a suitable operating range to control the transistors 312 to operate over a suitable impedance range for capacitor 314 to be variably engaged over a desired range. In this embodiment, as the effective capacitance (as seen by the inverter circuit 300) increases (CTL FINE increases), the operating frequency of the ring oscillator decreases. In some embodiments, pseudo inverter circuits without the controllably variable resistors are used. With tuning implemented with just the capacitor and control transistors, tuning ranges of several GHz per volt may be achieved. If wider frequency range is required, the coarse tuning can be included.

In the depicted embodiment, variable linear resistors 306 and NMOS transistors 308 are used in the pull-up legs to significantly reduce supply noise sensitivity. The linear resistors 306 are insensitive to supply noise. The gates of NMOS transistors 308 are connected to the supply voltage (which may correspond to a VCC or some other supplied voltage) to compensate for the resistor variation of other devices in circuit 300 due to supply noise Thus, compared with the pseudo inverter circuits of the prior art, the depicted inverter has better PSRR. Also, as the supply voltage goes up, PSRR improves. Thus, a trade-off between power consumption and PSRR occurs. In some embodiments, this may be a desired characteristic.

With reference to FIG. 4, one example of a computer system is shown. The depicted system generally comprises a processor 402 that is coupled to a power supply 404, a wireless interface 406, and memory 408. It is coupled to the power supply 404 to receive from it power when in operation. The wireless interface 406 is coupled to an antenna 410 to communicatively link the processor through the wireless interface chip 406 to a wireless network (not shown). Microprocessor 402 comprises one or more VCOs 403 such as are disclosed herein.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
a ring oscillator comprising a plurality of inverter stages, wherein at least one stage comprises an inverter with a controllably variable, linear load resistor to control the frequency of the oscillator.

2. The chip of claim 1, in which the at least one stage inverter is a pseudo differential inverter having complementary outputs.

3. The chip of claim 1, in which the at least one stage inverter has an associated supply and first and second pull-up legs each comprising an NMOS transistor with its gate coupled to the supply.

4. The chip of claim 1, in which the at least one stage inverter has a first pull-up leg comprising the controllably variable linear resistor and has a second pull-up leg with a second controllably variable linear resistor.

5. The chip of claim 4, comprising a controllably variable capacitor coupled between the first and second pull-up legs.

6. The chip of claim 1, in which the at least one stage inverter has a first pull-down leg comprising the controllably variable linear resistor and has a second pull-down leg with a second controllably variable linear resistor.

7. The chip of claim 6, in which the at least one stage inverter has an associated ground reference and the first and second pull-down legs each comprise a PMOS transistor with its gate coupled to the ground reference.

8. A chip, comprising:
a ring oscillator comprising a plurality of inverter stages, wherein at least one stage comprises an inverter with a controllably variable capacitor to control the frequency of the oscillator.

9. The chip of claim 8, in which the at least one stage inverter is a pseudo differential inverter having complementary outputs.

10. The chip of claim 9, in which the at least one stage inverter comprises a complementary inverter circuit having cross-coupled pairs of mirror-coupled transistors.

11. The chip of claim 10, in which the mirror coupled transistor pairs comprise NMOS transistors.

12. The chip of claim 11, in which the at least one stage inverter has an associated supply and first and second pull-up legs each comprising an NMOS transistor with its gate coupled to the supply.

13. The chip of claim 12, in which the first and second pull-up legs each comprise a controllably variable linear resistor to provide coarse frequency tuning adjustment.

14. The chip of claim 8, in which the at least one stage inverter has a first pull-down leg comprising a controllably variable linear resistor and has a second pull-down leg comprising a controllably variable linear resistor.

15. The chip of claim 14, in which the at least one stage inverter has an associated ground reference and the first and second pull-down legs each comprise a PMOS transistor with its gate coupled to the ground reference.

16. The chip of claim 15, in which the at least one stage inverter is a pseudo differential inverter having complementary outputs.

17. The chip of claim 15, in which the at least one stage inverter has an associated supply and first and second pull-up legs each comprising an NMOS transistor with its gate coupled to the supply.

18. A circuit comprising:
a pseudo differential inverter comprising:
a complementary inverter having a first leg between a first output node and a supply reference and having a second leg between a second output node and the supply reference;
the first and second legs each comprising a controllably variable linear resistor to tune the pseudo differential inverter.

19. The circuit of claim 18, in which the complementary inverter comprises mirror-coupled NMOS transistor pairs.

20. The circuit of claim 19, in which the supply reference is a high supply reference and the first and second legs are pull-up legs each comprising an NMOS transistor with its gate coupled to the supply reference.

21. A system, comprising:
(a) a microprocessor comprising a ring oscillator having a plurality of inverter stages, wherein at least one stage comprises an inverter with a controllably variable, linear load resistor to control the frequency of the oscillator;
(b) an antenna; and
(c) a wireless interface coupled to the microprocessor and to the antenna to communicatively link the microprocessor to a wireless network.
